(19) United States
(12) Patent Application Publication
(10) Pub. No.: US 2010/0288548 A1
(43) Pub. Date: Nov. 18, 2010

(54) CIRCUIT LAYOUT METHOD AND CIRCUIT BOARD FABRICATED BY THE SAME

(75) Inventor: Chien-Ho YEH, TAIPEI CITY (TW)

Correspondence Address: BRIAN M. MCINNIS, 12th Floor, Ruttonjee House, 11 Duddell Street, Hong Kong, HK

(73) Assignee: INVENTEC CORPORATION, TAIPEI CITY (TW)

(21) Appl. No.: 12/499,096

(22) Filed: Jul. 8, 2009

(30) Foreign Application Priority Data
May 15, 2009 (TW) 98116214

(51) Int. Cl. H05K 1/11; G06F 17/50

(52) U.S. Cl. 174/261; 716/8

(57) ABSTRACT

In a circuit layout method, a circuit layout diagram of a circuit board is provided, the circuit board including a plurality of pad symbols. Then, after information regarding a direction of the circuit board facing towards a solder oven when the circuit board passes through the solder oven in the future is obtained, an independent trailing pad symbol is added to a position behind the last pad symbol passing through the solder oven on the layout diagram corresponding to the circuit board. Thus, when the layout diagram is performing version update, the independent trailing pad symbol does not participate in the version update.

### RELATED APPLICATIONS

This application claims priority to Taiwan Application Serial Number 98116214, filed May 15, 2009, which is herein incorporated by reference.

### BACKGROUND

1. Field of Invention

The present invention relates to a circuit layout method. More particularly, the present invention relates to a circuit layout method for adding trailing pad symbol.

2. Description of Related Art

Referring to FIG. 1A, FIG. 1A is a schematic diagram showing a conventional circuit layout diagram without a functional pad symbol. In a process for fabricating a conventional circuit layout, while designing a circuit layout diagram 10 via a software program, an engineer will arrange one or more pad symbols 12 corresponding to pins of electronic elements at predetermined positions of a circuit board at which the respective electronic elements are allocated. Thus, when the circuit board is fabricated, the metal solder pad represented by the pad symbols 12 will be formed as expected at the corresponding positions of the circuit board, so as to perform a soldering process subsequently for bonding the pins of the electronic elements on the metal solder pads.

When the soldering process is performed and the circuit board needs to pass through a solder oven, due to the temperature setting of the solder over; or the ratio of components of the soldering material, the solder will be caused to form solder icicles on the pins of the last electronic elements of the circuit board passing through the solder oven in a moving direction D relative to the circuit board. However, the appearances of such solder icicles often do not meet the quality control requirements for the soldering process, thus lowering the degree of client satisfaction at the acceptance test of circuit board.

Referring to FIG. 1B, FIG. 1B is a schematic diagram showing a conventional circuit layout diagram generating a functional pads symbol. For overcoming the aforementioned disadvantages, the engineer replaces the pad symbol 12 corresponding to the pins of electronic elements passing through the solder oven as a functional pad symbol 14. After the functional pad symbol 14 is based to form a metal solder pad, such metal solder pad also may be provided for soldering one pin of electronic element, and meanwhile for solder trailing to reduce the formation of solder icicles.

Thus, when the circuit board having the metal solder pad corresponding to the functional pad symbol 14 passes through the solder oven, even under the affects of the temperature setting of the solder over; or the ratio of components of the soldering material, the solder will still be evenly attached to the metal solder pad corresponding to the functional pad symbol 14, so that the defective rate due to the formation of solder icicles can be lowered.

However, although the functional pad 14 may be used to resolve the problems of solder icicles described above, yet whenever the engineer performs version update on the circuit layout diagram 10 via a software program, the software program will base on a new-versioned pad symbol 12 in a database to replace the old-versioned pad symbol 12, wherein the aforementioned functional pad symbol 14 is also replaced and recovered back to the original pad symbol 12, referring back to FIG. 1A. Consequently, after the engineer learns the sequence of the metal solder pads passing through the solder oven, the pad symbol corresponding to the last pin of electron element on the circuit layout diagram has to be replaced again as the aforementioned functional pad symbol 14 (as shown in FIG. 1B).

As such, for a plurality of the last pad symbols which have to be replaced; or the circuit layout diagram which has to undergo sever times of version update, the engineer has to repeatedly change the last pad symbol to functional pad symbols, thus not only consuming quite a lot manpower and time, but also indirectly increasing the fabrication cost of circuit board. Meanwhile, it is relatively more difficult to maintain the data of respective versions of pad symbols, thus resulting in difficulty for the engineer to administrate the data.

### SUMMARY

In view of the aforementioned shortcomings, the present invention provides a circuit layout method, so that an engineer does not need to repeatedly change the last pad symbol whenever performing version update on a circuit layout diagram. Therefore, for a plurality of the last pad symbols which have to be replaced; or the circuit layout diagram which has to undergo sever times of version update, the manpower and time, and the fabrication cost of circuit board can be greatly saved.

According to the aforementioned object, a circuit layout method is provided, and includes providing a circuit layout diagram of a circuit board is provided, the circuit board including a plurality of pad symbols. After information regarding a direction of the circuit board facing towards a solder oven when the circuit board passes through the solder oven in the future is obtained, an independent trailing pad symbol is added to a position behind the last pad symbol passing through the solder oven on the layout diagram corresponding to the circuit board. When the layout diagram is performing version update, the independent trailing pad symbol does not participate in the version update.

In one embodiment, when the circuit layout diagram is performing the version update, a plurality of new-versioned pad symbols are used to replace the pad symbols originally on the circuit board, and the independent trailing pad symbol is reserved at its relative position on the circuit layout diagram.

In another embodiment, the independent trailing pad symbol has a shape showing a thickness gradually decreasing towards a direction away from the last pad symbol on the circuit layout diagram, such as a triangle or a water droplet shape.

In another embodiment, the independent trailing pad symbol is adjacent to and spaced from the last metal solder pad of the circuit board at a distance, and there is a line surrounding the outline of the independent trailing pad symbol with a gap.

In one aspect, a circuit board is provided and includes a plate, a plurality of metal solder pads and at least one trailing pad. The metal solder pads are distributed on the rectangular plate. The trailing pad is located on one side of one of the metal solder pads which is located nearest to an edge of the rectangular plate, wherein the trailing pad is spaced from the one of the metal solder pads at a distance.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1A is a schematic diagram showing a conventional circuit layout diagram without a functional pad symbol;

FIG. 1B is a schematic diagram showing a conventional circuit layout diagram generating a functional pads symbol;

FIG. 2A is a schematic diagram showing a partial circuit layout diagram generating a trailing pad symbol according to an embodiment of the present invention;

FIG. 2B is a schematic diagram showing a corresponding circuit board fabricated in accordance with the partial circuit layout diagram shown in FIG. 2B; and

FIG. 3 is a flow chart of a circuit layout method according to the embodiment of the present invention.

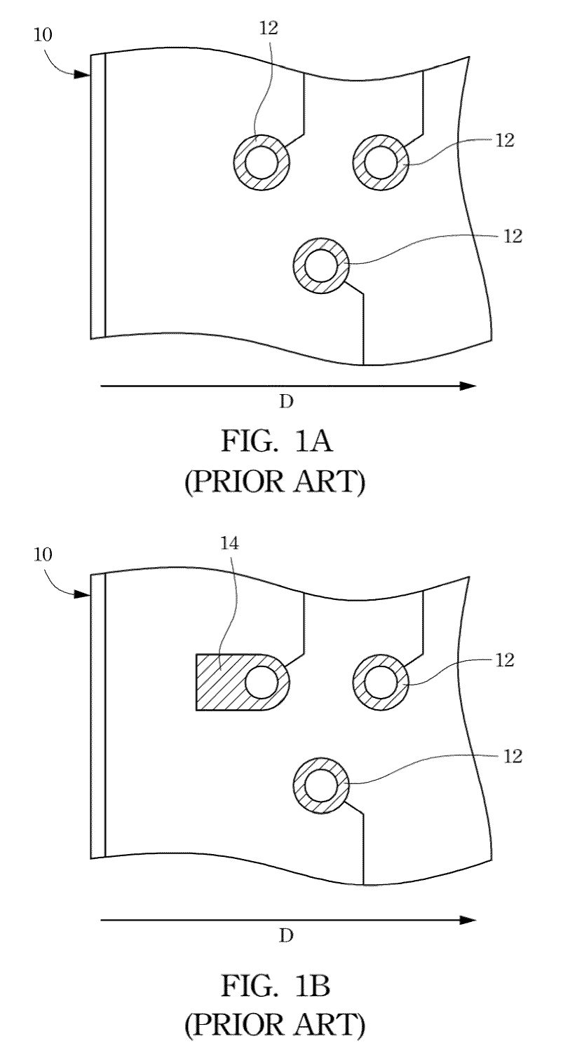

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention provides a circuit layout method, which is applied to a design procedure of circuit layout prior to fabricating a circuit board, and is suitable for use in circuit board layout. The concept for resolving the conventional problems is to follow the rules that a software program will replace old-versioned pad symbols one by one with new-versioned pad symbols in a database when a circuit layout diagram is performing version update on the software program, so as to provide a trailing pad symbol which does not participate in the version update, thus saving the time and cost for repeatedly modifying the last pad symbol.

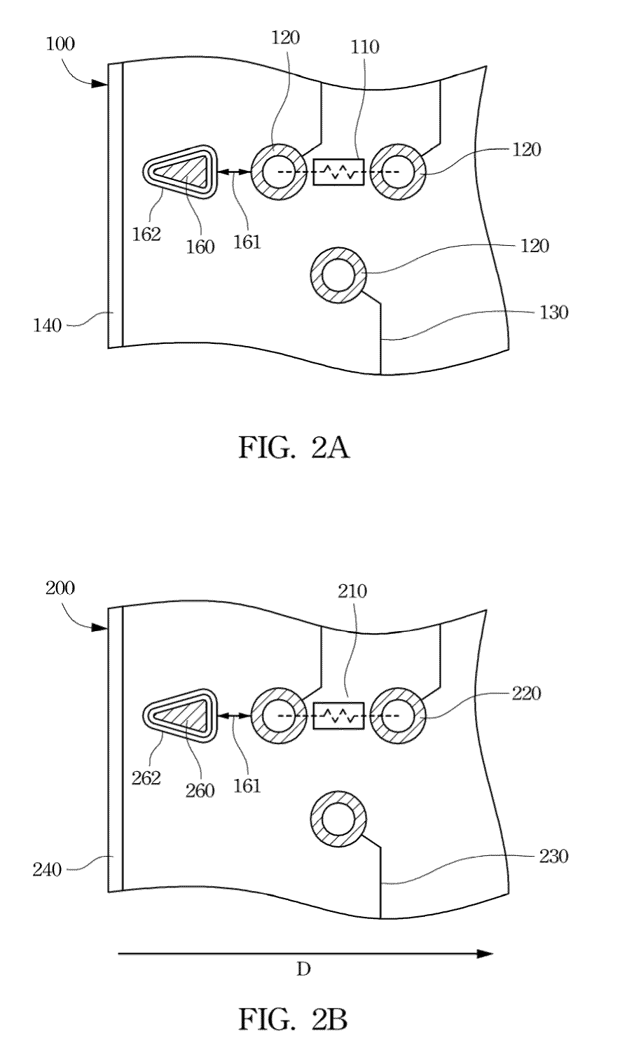

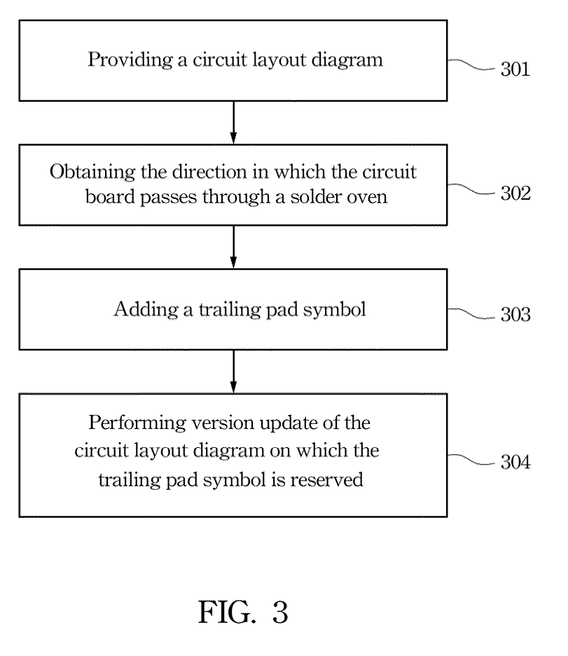

FIG. 2A is a schematic diagram showing a partial circuit layout diagram generating a trailing pad symbol according to an embodiment of the present invention; FIG. 2B is a schematic diagram showing a corresponding circuit board fabricated in accordance with the partial circuit layout diagram shown in FIG. 2B; and FIG. 3 is a flow chart of a circuit layout method according to the embodiment of the present invention. Please refer to FIG. 3 accompanying with FIG. 2A and FIG. 2B. An embodiment of the circuit layout method includes the following steps.

Step 301 is performed for providing one or more circuit layout diagram 100. As shown in FIG. 2A, the circuit layout diagram 100 includes the information related to a plurality of local symbols 110 used for allocating the electronic element (such as chips, resistors and capacitors, etc.), pad symbols 120,wiring symbols 130 and a grounding symbol 140, etc., wherein the pad symbols stand for metal solder pads formed on a circuit board 200 for bonding the pins of the electronic elements. Thus, the circuit board 200 as shown in FIG. 2B can be fabricated in accordance with the information of the circuit layout diagram(s) 100, and the aforementioned local symbols 110, pad symbols 120, wiring symbols 130 and grounding symbol 140 will be used as expected to form an allocation area 210 of electronic elements, metal solder pads 220, wirings 230 and a ground 240 on the corresponding positions of the circuit board 200, so as to perform a soldering process subsequently.

Step 302 is performed for obtaining information regarding a direction in which the circuit board passes through a solder oven. The information regarding the direction D of the circuit board 200 facing towards the solder oven while the circuit board 200 is passing through the solder oven after the circuit layout diagram 100 is used to fabricate the circuit board 200 in the future is obtained, so that an engineer may know the sequence of the metal solder pads 220 (pad symbols 200) of the circuit board 200 passing through the solder oven. When the circuit board 200 is a rectangular plate, it can be rotated or flipped over so as to make a longer or shorter side of the circuit board 200 face towards the solder oven, and thus the circuit board 200 may pass through the solder oven in this direction for performing the soldering process.

Step 303 is performed for adding a trailing pad symbol 160. According to the aforementioned information regarding the direction D of the circuit board 200 facing towards the solder oven, at least one independent trailing pad symbol 160 is added to a position behind the last pad symbol 120 passing through the solder oven on the layout diagram 100 corresponding to the circuit board 200, so as to form a trailing pad 260 behind the last metal solder pad 220 passing through the solder oven. Similarly, the trailing pad 260 is located on one side of the metal solder pads which is located nearest to an edge of the rectangular plate, and is between the metal solder pads and the edge of the rectangular plate.

It is noted that the trailing pad symbol 160 is an independent element, so that the trailing pad symbol 160 is spaced from the last pad symbol 120 at a distance 161, although it is located nearest to the last pad symbol 120. Meanwhile, the trailing pad symbol 160 is not any version of solder symbol 120 in the database, meaning that it is not used to allocate the pins of electronic elements. Thus, after the circuit board 200 passes through the solder oven in the future, the trailing pad 260 may provide a trailing path of solder to reduce the formation of solder icicles.

In this embodiment, the shape of the independent trailing pad symbol 160 (i.e. the trailing pad 260) shows a thickness gradually decreasing towards a direction away from the last pad symbol 120 (i.e. the metal solder pad 220), such as a triangle or a water droplet shape.

Further, in this embodiment, on the circuit layout diagram 100, there is a line 162 surrounding the outline of the trailing pad symbol 160 with a gap. Thus, after the circuit board 200 is fabricated thereby in the future, the outline of the trailing pad 260 is an electrically nonconductive printed line 262. Therefore, the printed line 262 will enhance separation of the trailing pad 260 from the solder located at the adjacent metal solder pad 220 when the circuit board 200 passes through the solder oven in the future.

Further, the circuit layout diagram 100 may also have a plurality of pad symbols 120 which are the last ones passing through the solder oven at the same, and thus it is likely to have a plurality of trailing pad symbols 160.

Step 304 is performed for performing version update of the circuit layout diagram 100.

When step 304 is performed, a plurality of updated (new-versioned) pad symbols 120 in the database are applied to the relative positions of the circuit layout diagram 100 to replace the old-versioned pad symbols 120. Referring back to FIG. 2A, since the aforementioned trailing pad symbols 160 do not participate in the version update of the circuit layout diagram 100, the trailing pad symbols 160 can be reserved at their relative position on the circuit layout diagram 100, and will not be replaced and disappear from the circuit layout diagram 100.

Therefore, the engineer does not need to modify the last pad symbol 120 repeatedly. For a plurality of the last pad symbols 120 which have to be replaced; or the circuit layout diagram which has to undergo sever times of version update, the present embodiment may save a lot of manpower and time, and fabrication cost of the circuit board 200. In case the position of the pad symbol 120 adjacent to the trailing pad symbol 160 is changed, the engineer merely needs to fine tune the relative relationship between the trailing pad symbol 160 and the adjacent pad symbol 120.

All of the steps described above for performing the circuit layout method of the present invention may be accomplished by a circuit layout software program in a computer, thereby providing the circuit layout diagram; obtaining the information regarding the direction in which the circuit board passes through the solder oven; adding the trailing pad symbol; and updating the circuit layout diagram.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit layout method, comprising:
providing a circuit layout diagram of a circuit board is provided, the circuit board comprising a plurality of pad symbols, each of the pad symbols representing a metal solder pad of the circuit board; and
adding an independent trailing pad symbol to a position associated with one of the pad symbols on the layout diagram, wherein the one of the pad symbols is corresponding to the last metal solder pad of the circuit board passing through the solder oven, and the independent trailing pad symbol is positioned behind the last metal solder pad of the circuit board, and the independent trailing pad symbol does not participate in version update when the circuit layout diagram is performing the version update.

2. The method as claimed in claim 1, wherein when the circuit layout diagram is performing the version update, a plurality of new-versioned pad symbols are used to replace the pad symbols originally on the circuit board, and the independent trailing pad symbol is reserved at its relative position on the circuit layout diagram.

3. The method as claimed in claim 1, wherein the independent trailing pad symbol has a shape showing a thickness gradually decreasing towards a direction away from the last pad symbol on the circuit layout diagram.

4. The method as claimed in claim 3, wherein the shape of the independent trailing pad symbol is a triangle or a water droplet shape.

5. The method as claimed in claim 1, wherein the independent trailing pad symbol is adjacent to and spaced from the last metal solder pad of the circuit board at a distance.

6. The method as claimed in claim 5, wherein there is a line surrounding the outline of the independent trailing pad symbol with a gap.

7. A circuit board, comprising:
a rectangular plate;
a plurality of metal solder pads distributed on the rectangular plate; and
at least one trailing pad located on one side of one of the metal solder pads which is located nearest to an edge of the rectangular plate, wherein the trailing pad is located between the one of the metal solder pads and the edge of the rectangular plate;
wherein, the trailing pad is spaced from the one of the metal solder pads at a distance.

8. The circuit board as claimed in claim 7, wherein the trailing pad has a shape showing a thickness gradually decreasing towards a direction away from the one of the metal solder pads.

9. The circuit board as claimed in claim 8, wherein the shape of the trailing pad is a triangular or a water droplet.

10. The circuit board as claimed in claim 7, wherein there is an electrically nonconductive printed line surrounding the outline of the trailing pad with a gap.
